(19) United States
(12) Patent Application Publication
(10) Pub. No.: US 2025/0047256 A1
(43) Pub. Date: Feb. 6, 2025

(54) ACOUSTIC WAVE DEVICE AND METHOD OF MANUFACTURING SAME

(71) Applicant: Murata Manufacturing Co., Ltd., Nagaokakyo-shi (JP)

(72) Inventor: Masakazu MIMURA, Nagaokakyo-shi (JP)

(21) Appl. No.: 18/918,777

(22) Filed: Oct. 17, 2024

Related U.S. Application Data
(63) Continuation of application No. PCT/JP2023/015606, filed on Apr. 19, 2023.
(60) Provisional application No. 63/332,785, filed on Apr. 20, 2022.

(51) Int. Cl. H03H 9/02; H03H 3/02

(52) U.S. Cl. CPC H03H 9/02015; H03H 3/02; H03H 9/02086; H03H 9/02157; H03H 9/02228

(57) ABSTRACT

An acoustic wave device includes a support including an energy confinement layer, a piezoelectric layer on one principal surface of the support and covering the energy confinement layer, a functional electrode on one principal surface of the piezoelectric layer and at least partially overlapping the energy confinement layer, and a dielectric film on a principal surface of the piezoelectric layer on an opposite side from the energy confinement layer. The piezoelectric layer includes a functional electrode portion including the functional electrode, and a portion other than the functional electrode portion. The dielectric film is provided in at least the functional electrode portion. A thickness of a portion of the dielectric film in the functional electrode portion is larger than a thickness of the dielectric film in the portion other than the functional electrode portion.

### CROSS REFERENCE TO RELATED APPLICATIONS

This application claims the benefit of priority to Provisional Application No. 63/332,785 filed on Apr. 20, 2022 and is a Continuation Application of PCT Application No. PCT/JP2023/015606 filed on Apr. 19, 2023. The entire contents of each application are hereby incorporated herein by reference.

### BACKGROUND OF THE INVENTION

### 1. Field of the Invention

The present invention relates to acoustic wave devices and methods of manufacturing the same.

### 2. Description of the Related Art

An acoustic wave device including a piezoelectric layer made of lithium niobate or lithium tantalate has heretofore been known.

Japanese Unexamined Patent Application Publication No. 2012-257019 discloses an acoustic wave device including a support body provided with a hollow portion, a piezoelectric substrate provided on the support body to overlap the hollow portion, and an IDT (interdigital transducer) electrode provided on the piezoelectric substrate to overlap the hollow portion, the acoustic wave device being configured to cause the IDT electrode to excite a plate wave, in which an end edge portion of the hollow portion does not include a straight portion that extends parallel to a direction of propagation of the plate wave excited by the IDT electrode.

International Publication No. WO 2022/014440 discloses an acoustic wave device including a support substrate, a piezoelectric layer provided on the support substrate, a functional electrode provided on the piezoelectric layer, and a first electrode film and a second electrode film provided on the piezoelectric layer, respectively, opposed to each other, and having electric potentials different from each other. When a region located between the first electrode film and the second electrode film in plan view is defined as a region between the electrode films and a region overlapping the first electrode film or the second electrode film in plan view is defined as a region immediately below the electrode film, a thickness of at least a portion of the piezoelectric layer in the region between the electrode films is smaller than a thickness of the piezoelectric layer in the region immediately below the electrode film.

As described in Japanese Unexamined Patent Application Publication No. 2012-257019 and International Publication No. WO 2022/014440, in the acoustic wave device in which the piezoelectric layer is formed on the support substrate and the electrode film is formed thereon, application of an electric signal to the electrode film causes application of a voltage not only to a resonator necessary for obtaining desired characteristics but also to the piezoelectric layer located between routed wires. In this case, a bulk wave is excited in a thickness direction (z direction) of the support substrate. If this bulk wave occurs, tiny ripples may appear in device characteristics.

International Publication No. WO 2022/014440 discloses a technique for suppressing excitation of a bulk wave and thus suppressing ripples by removing a piezoelectric layer located between wires. However, this method cannot keep a certain degree of the piezoelectric layer from extending out of wiring electrodes. Thus, ripples caused by excitation of the bulk wave at a portion between the wires where the piezoelectric layer extends out become problematic. For this reason, it is difficult to completely suppress the ripples.

### SUMMARY OF THE INVENTION

Example embodiments of the present invention provide acoustic wave devices that are each able to reduce or prevent an impact of ripples caused by a bulk wave on device characteristics. Moreover, example embodiments of the present invention provide methods of manufacturing such acoustic wave devices.

An acoustic wave device according to an example embodiment of the present invention includes a support including an energy confinement layer at one principal surface, a piezoelectric layer on the one principal surface of the support and covering the energy confinement layer, a functional electrode on at least one principal surface of the piezoelectric layer, and at least partially overlapping the energy confinement layer when viewed in a thickness direction of the piezoelectric layer, and a dielectric film on a principal surface of the piezoelectric layer on an opposite side from the energy confinement layer. The piezoelectric layer includes a functional electrode portion including the functional electrode, and a portion other than the functional electrode portion. The dielectric film is provided on at least the functional electrode portion. A thickness of at least a portion of the dielectric film on the functional electrode portion is larger than a thickness of the dielectric film on the portion other than the functional electrode portion.

A method of manufacturing an acoustic wave device according to an example embodiment of the present invention includes preparing an intermediate structure including a support including an energy confinement layer at one principal surface, a piezoelectric layer on the one principal surface of the support and covering the energy confinement layer, and a functional electrode on at least one principal surface of the piezoelectric layer, and at least partially overlapping the energy confinement layer when viewed in a thickness direction of the piezoelectric layer, in which the piezoelectric layer is formed from a functional electrode portion including the functional electrode, and a portion other than the functional electrode portion, forming a dielectric film on the intermediate structure to cover at least the functional electrode portion at a principal surface of the piezoelectric layer on an opposite side from the energy confinement layer, and adjusting a thickness of the dielectric film formed on the intermediate structure such that a thickness of at least a portion of the dielectric film on the functional electrode portion is larger than a thickness of the dielectric film on the portion other than the functional electrode portion.

According to example embodiments of the present invention, it is possible to provide acoustic wave devices that are each able to reduce or prevent an impact of ripples caused by a bulk wave on device characteristics. Moreover, according to example embodiments of the present invention, it is possible to provide methods of manufacturing such acoustic wave devices.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a cross-sectional view schematically illustrating an example of an acoustic wave device according to a first example embodiment of the present invention.

FIG. 2 is a plan view schematically illustrating an example of a layout of the acoustic wave device according to the first example embodiment of the present invention.

FIG. 3 is a plan view illustrating regions where a bulk wave is excited in the acoustic wave device depicted in FIG. 2.

FIG. 4 is a plan view schematically illustrating an example of a functional electrode portion in the acoustic wave device depicted in FIG. 2.

FIG. 5 is a cross-sectional view schematically illustrating an example of a dielectric film provided on the functional electrode portion.

FIG. 6 is a cross-sectional view schematically illustrating another example of the dielectric film provided on the functional electrode portion.

FIG. 7 is a cross-sectional view schematically illustrating an example of a dielectric film provided on a portion other than the functional electrode portion.

FIG. 8A is a graph depicting an example of resonator characteristics in a narrow band, and FIG. 8B is a graph depicting an example of resonator characteristics in a wide band.

FIG. 9A depicting an is a graph example of characteristics of a bulk wave in the narrow band, and FIG. 9B is a graph depicting an example of characteristics of the bulk wave in the wide band.

FIG. 10 is a cross-sectional view schematically illustrating a configuration of a portion other than the functional electrode portion used for a simulation.

FIGS. 11A to 11H are graphs depicting simulation results.

FIG. 12 is a cross-sectional view schematically illustrating an example of a functional electrode portion in an acoustic wave device according to a second example embodiment of the present invention.

FIG. 13 is a cross-sectional view schematically illustrating an example of a step of preparing an intermediate structure according to an example embodiment of the present invention.

FIG. 14 is a cross-sectional view schematically illustrating an example of a step of forming a dielectric film on the intermediate structure according to an example embodiment of the present invention.

FIGS. 15A and 15B are cross-sectional views schematically illustrating an example of a step of adjusting a thickness of the dielectric film formed on the intermediate structure according to an example embodiment of the present invention.

FIG. 16 is a cross-sectional view schematically illustrating another example of a step of forming a dielectric film on the intermediate structure according to an example embodiment of the present invention.

FIGS. 17A and 17B are cross-sectional views schematically illustrating another example of a step of adjusting a thickness of the dielectric film formed on the intermediate structure according to an example embodiment of the present invention.

FIG. 18 is a cross-sectional view schematically illustrating another example of the acoustic wave device according to the first example embodiment of the present invention.

FIG. 19 is a schematic perspective view illustrating external appearance of an example of an acoustic wave device that uses a thickness-shear mode bulk wave.

FIG. 20 is a plan view illustrating an electrode structure on a piezoelectric layer of the acoustic wave device depicted in FIG. 19.

FIG. 21 is a cross-sectional view of a portion taken along the A-A line in FIG. 19.

FIG. 22 is a schematic elevational cross-sectional view for explaining a Lamb wave that propagates on a piezoelectric film of an acoustic wave device.

FIG. 23 is a schematic elevational cross-sectional view for explaining a thickness-shear mode bulk wave that propagates on a piezoelectric layer of an acoustic wave device.

FIG. 24 is a diagram illustrating a direction of amplitude of the thickness-shear mode bulk wave.

FIG. 25 is a diagram illustrating an example of resonance characteristics of the acoustic wave device depicted in FIG. 19.

FIG. 26 is a diagram illustrating a relationship between a value d/2p and a fractional bandwidth as a resonator of the acoustic wave device in a case where a center-to-center distance of electrodes located adjacent to each other is defined as a value p and a thickness of a piezoelectric layer is defined as a value d.

FIG. 27 is a plan view of another example of an acoustic wave device that uses a thickness-shear mode bulk wave.

FIG. 28 is a reference diagram illustrating an example of the resonance characteristics of the acoustic wave device depicted in FIG. 19.

FIG. 29 is a diagram illustrating a relationship between a fractional bandwidth when constructing numerous acoustic wave resonators in accordance an example embodiment of the present invention and a phase rotation amount of impedance of a spurious response standardized at about 180 degrees as a magnitude of the spurious response.

FIG. 30 is a diagram illustrating a relationship among the value d/2p, a metallization ratio MR, and the fractional bandwidth.

FIG. 31 is a diagram illustrating a map of the fractional bandwidth relative to Euler angles (0°, 0, $) of LiNbO₃ in a case of bringing a value d/p infinitesimally close to 0.

FIG. 32 is a partially cutaway perspective view for explaining an example of an acoustic wave device that uses a Lamb wave.

FIG. 33 is a cross-sectional view schematically illustrating an example of an acoustic wave device that uses a bulk wave.

### DETAILED DESCRIPTION OF THE EXAMPLE EMBODIMENTS

Acoustic wave devices according to example embodiments of the present invention will be described below with reference to the drawings.

An acoustic wave device according to an example embodiment of the present invention includes a piezoelectric layer made of, for example, lithium niobate or lithium tantalate, and a first electrode and a second electrode opposed to each other in a direction intersecting with a thickness direction of the piezoelectric layer.

A bulk wave in a thickness-shear mode such as a thickness-shear primary mode is used in an example embodiment. The first electrode and the second electrode are electrodes located adjacent to each other in an example embodiment. When a thickness of the piezoelectric layer is defined as a value d and a center-to-center distance between the first electrode and the second electrode is defined as a value p, a value d/p is set equal to or less than about 0.5, for example. Accordingly, it is possible to increase a Q-factor even in the case where downsizing is performed.

A Lamb wave as a plate wave is used in an example embodiment. Thus, resonance characteristics attributed to the Lamb wave can be obtained.

An acoustic wave device according to an example embodiment of the present invention includes a piezoelectric layer, and an upper electrode and a lower electrode opposed to each other in a thickness direction of the piezoelectric layer while interposing the piezoelectric layer therebetween. The piezoelectric layer is made of lithium niobate or lithium tantalate, for example, or preferably made of lithium niobate single crystal or lithium tantalate single crystal, for example. A bulk wave is used in the present example embodiment.

The present invention will be clarified below by describing specific example embodiments of the present invention with reference to the drawings.

The drawings represented below are schematic, and dimensions, scales such as aspect ratios, and so forth may be different from those of actual products.

The respective example embodiments described in the present specification are exemplary, and partial replacements or combinations of configurations across the different example embodiments are also included in the present invention. A simple expression “the acoustic wave device of the present invention” will be used when it is not necessary to distinguish between the respective example embodiments.

### First Example Embodiment

In an acoustic wave device according to a first example embodiment of the present invention, an energy confinement layer is a hollow portion.

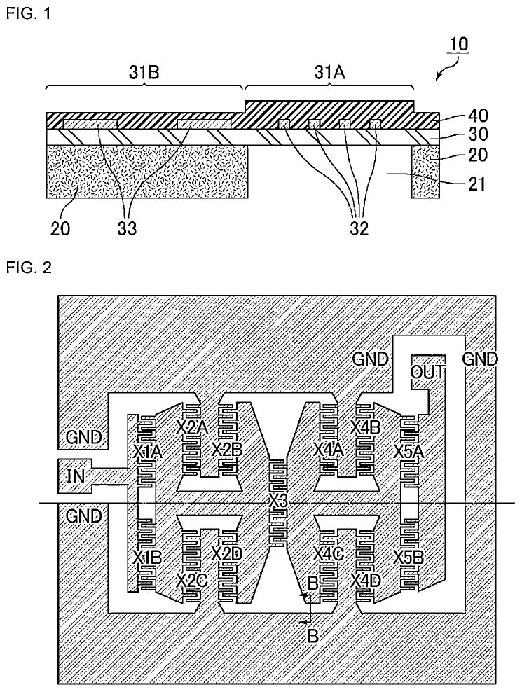

FIG. 1 is a cross-sectional view schematically illustrating an example of the acoustic wave device according to the first example embodiment of the present invention.

An acoustic wave device 10 illustrated in FIG. 1 includes a support 20, a piezoelectric layer 30, functional electrodes 32, and a dielectric film 40.

The support 20 includes a hollow portion 21 as an example of an energy confinement layer. The hollow portion 21 may penetrate or need not penetrate the support 20 in a thickness direction (a vertical direction in FIG. 1). In the example embodiment illustrated in FIG. 1, the hollow portion 21 penetrates the support 20 in the thickness direction. When the hollow portion 21 does not penetrate the support 20 in the thickness direction, the support 20 includes the hollow portion 21 at one principal surface (an upper principal surface in FIG. 1).

The support 20 includes a support substrate. The support substrate is made of silicon (Si), for example.

The support 20 may include an intermediate layer (also referred to as a joining layer or an insulating layer) on one principal surface including the piezoelectric layer 30. For example, the support 20 may include the support substrate, and the intermediate layer provided between the support substrate and the piezoelectric layer. The intermediate layer is made of silicon oxide (SiOₓ) such as silicon dioxide (SiO₂), for example.

When the support 20 includes the support substrate and the intermediate layer, the hollow portion 21 may penetrate the intermediate layer in the thickness direction or the hollow portion 21 may be provided so as not to penetrate the intermediate layer in the thickness direction.

The piezoelectric layer 30 is provided on the one principal surface of the support 20 so as to cover the hollow portion 21.

The piezoelectric layer 30 is made of lithium niobate (LiNbOₓ) or lithium tantalate (LiTaOₓ), for example. In this case, the piezoelectric layer 30 may be made LiNbO₃ or LiTaO₃, for example.

The functional electrodes 32 are provided on at least the one principal surface of the piezoelectric layer 30, and at least a portion of the functional electrodes 32 overlaps the hollow portion 21 when viewed in the thickness direction (the vertical direction in FIG. 1) of the piezoelectric layer 30. The functional electrodes 32 may be provided to entirely or substantially entirely overlap the hollow portion 21 or the functional electrodes 32 may be provided to partially overlap the hollow portion 21 when viewed in the thickness direction of the piezoelectric layer 30.

The piezoelectric layer 30 includes a functional electrode portion 31A including the functional electrodes 32, and a portion 31B other than the functional electrode portion. The functional electrode portion 31A corresponds to a resonator.

The functional electrodes 32 provided in the functional electrode portion 31A are IDT electrodes provided on the one principal surface of the piezoelectric layer 30, for example.

The portion 31B other than the functional electrode portion is a routed wiring portion, for example. In this case, the portion 31B other than the functional electrode portion includes wiring electrodes 33 to be connected to the functional electrodes 32.

Each wiring electrode 33 is two-layered wiring, for example.

The dielectric film 40 is provided on a principal surface (a principal surface on an upper side in FIG. 1) of the piezoelectric layer 30 on an opposite side from the hollow portion 21, and is provided on at least the functional electrode portion 31A. At the principal surface (the principal surface on the upper side in FIG. 1) of the piezoelectric layer 30 on the opposite side from the hollow portion 21, the dielectric film 40 may be provided in the functional electrode portion 31A and the portion 31B other than the functional electrode portion, or be provided only in the functional electrode portion 31A.

For example, the dielectric film 40 is made of silicon oxide such as silicon dioxide (SiO₂), silicon nitride such as Si₃N₄, silicon oxynitride, tantalum pentoxide, and the like.

By providing the dielectric film 40 on the piezoelectric layer 30, it possible to differentiate frequencies s among resonators in the same substrate or to adjust the frequencies of the resonators.

As illustrated in FIG. 1, a thickness of the dielectric film 40 provided on the piezoelectric layer 30 is different between the functional electrode portion 31A being the resonator and the portion 31B other than the functional electrode portion. To be more precise, the thickness of at least a portion of the dielectric film 40 provided om the functional electrode portion 31A is larger than the thickness of the dielectric film 40 provided in the portion 31B other than the functional electrode portion. Accordingly, a generation frequency of a bulk wave can be shifted from a frequency band used by the device. Thus, it is possible to reduce an impact of ripples generated by the bulk wave on the device characteristics.

Here, the thickness of the entire or substantially the entire dielectric film 40 provided in the functional electrode portion 31A may be larger than the thickness of the dielectric film 40 provided in the portion 31B other than the functional electrode portion, or the thickness of a portion of the dielectric film 40 provided in the functional electrode portion 31A may be larger than the thickness of the dielectric film 40 provided in the portion 31B other than the functional electrode portion. Alternatively, the thickness of the dielectric film 40 provided in the portion 31B other than the functional electrode portion may be equal to zero. That is to say, the dielectric film 40 need not be provided in the portion 31B other than the functional electrode portion.

For example, in a case of an XBAR (transversely-excited film bulk acoustic resonator) element in which the IDT electrodes defining and functioning as the functional electrodes 32 are provided on the one principal surface of the piezoelectric layer 30, both of a vibration excited by the resonator and a vibration excited in the routed wiring are thickness-shear vibrations excited at an electric field in a planar direction of the piezoelectric layer 30. That is to say, both of a wave used in the device characteristics by the resonator and the bulk wave excited at the routed wiring portion are waves of the same type which are excited in the same or substantially the same frequency bands. Accordingly, the frequency generated by the bulk wave can be set higher than the frequency of the device by providing the dielectric film in the routed wiring portion thinner than the dielectric film at the resonator.

Formation of the dielectric film on the piezoelectric layer has also been provided in the related art in order to differentiate the frequencies among resonators in the same substrate or to adjust the frequencies of the resonators.

However, in the case of differentiating the frequencies by using the thicknesses of the dielectric film, it is a general practice to provide a dielectric film in a thickness necessary for resonators on a low-frequency side on the entire or substantially the entire surface of the piezoelectric layer in the first place and then selectively etching the dielectric film on resonators on a high-frequency side. In this case, the dielectric film on the resonators on the high-frequency side is selectively etched after providing the dielectric film on a portion other than the resonator. Accordingly, the thickness of the dielectric film on the resonators on the low-frequency side is equivalent to the thickness of the dielectric film at the portion other than the resonator.

Moreover, in a case of individually adjusting the frequencies of the respective resonators, it is a general practice to selectively etch only the resonator. In this case, the dielectric film is left over at the portion other than the resonator. As a consequence, the portion other than the resonator has a larger thickness of the dielectric film as compared to that at the resonator.

As described above, in the configuration of the related art, the thickness of the dielectric film provided in the resonator is generally equivalent to the thickness of the dielectric film provided in the portion other than the resonator or smaller than the thickness of the dielectric film provided in the portion other than the resonator.

FIG. 2 is a plan view schematically illustrating an example of a layout of the acoustic wave device according to the first example embodiment of the present invention.

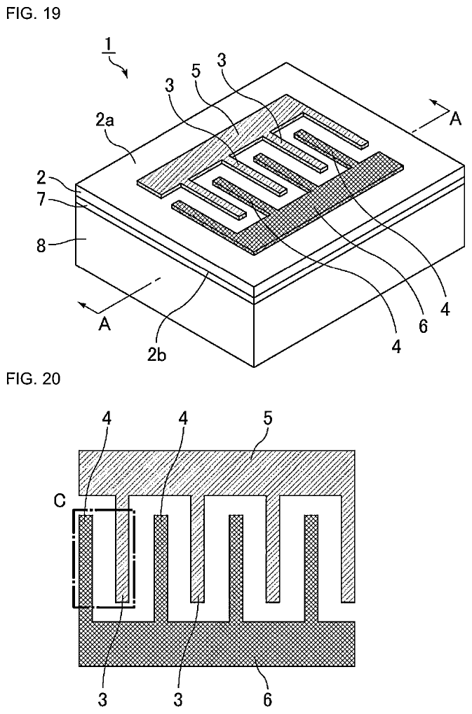

FIG. 2 is created based on FIG. 19 in the specification of U.S. Patent Application Publication No. 2020/0021271. In the example illustrated in FIG. 2, functional electrode portions X1A and X1B, X2A and X2C, X2B and X2D, X3, X4A and X4C, X4B and X4D, and X5A and X5B are symmetrically or substantially symmetrically disposed with respect to a center axis indicated with a dash-dotted line.

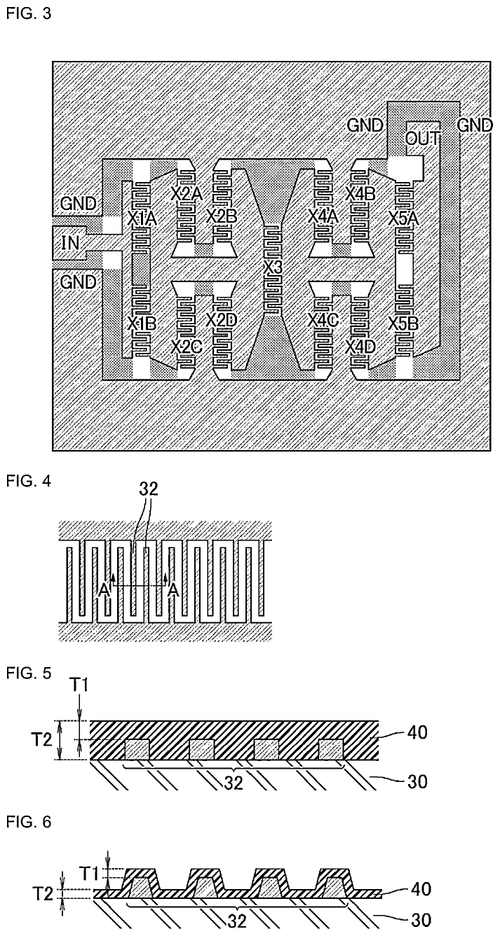

FIG. 3 is a plan view illustrating regions where a bulk wave is excited in the acoustic wave device depicted in FIG. 2.

As illustrated in FIG. 3, the bulk wave is excited in regions (shaded regions in FIG. 3) interposed by wiring electrodes (IN, OUT, GND) having different electric potentials. The frequency of the bulk wave is determined by the thickness of the dielectric film of this portion. Accordingly, the thickness of the dielectric film of this portion is set smaller than the thickness of the dielectric film of the functional electrode portions.

FIG. 4 is a plan view schematically illustrating an example of a functional electrode portion in the acoustic wave device depicted in FIG. 2.

In the functional electrode portion such as X1A in FIG. 2, the functional electrodes 32 have a comb-shaped electrode structure as illustrated in FIG. 4.

FIG. 5 is a cross-sectional view schematically illustrating an example of the dielectric film provided in the functional electrode portion. FIG. 6 is a cross-sectional view schematically illustrating another example of the dielectric film provided in the functional electrode portion. Note that FIGS. 5 and 6 represent a cross-section taken along the A-A line in FIG. 4.

When a surface of the dielectric film 40 is planarized on the piezoelectric layer 30 as illustrated in FIG. 5, the “thickness of the dielectric film provided in the functional electrode portion” represents a thickness of a portion denoted by a reference sign T2, because the frequency of the acoustic wave excited by the above-described functional electrode portion (the resonator) is influenced more by the thickness of the portion indicated with the reference sign T2 (that is to say, a thickness of the dielectric film 40 provided on the piezoelectric layer 30 between the electrode fingers of the functional electrodes 32) than by a thickness of a portion denoted by a reference sign T1 (that is to say, a thickness of the dielectric film 40 provided on the functional electrodes 32).

The “thickness of the dielectric film provided in the functional electrode portion” represents the thickness of a portion denoted by the reference sign T2 similarly in the case where the thickness of the dielectric film 40 is constant as illustrated in FIG. 6.

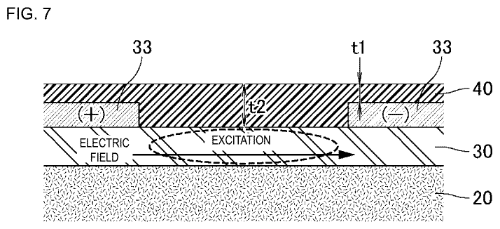

FIG. 7 is a cross-sectional view schematically illustrating an example of the dielectric film provided in a portion other than the functional electrode portion. FIG. 7 represents a cross-section taken along the B-B line in FIG. 2.

In a case where the dielectric film 40 is provided on the piezoelectric layer 30 and the wiring electrodes 33 as illustrated in FIG. 7, the “thickness of the dielectric film provided in the portion other than the functional electrode portion” represents the thickness of a portion denoted by a reference sign t2. The above-described bulk wave is excited by the piezoelectric layer 30 in a region where no electrodes are provided between the wiring electrodes 33. Accordingly, the thicknesses of the piezoelectric layer 30 and the dielectric film 40 in this portion mainly determine the frequency of the excited bulk wave, and the thickness at the portion denoted by the reference sign t2 (that is to say, the thickness of the dielectric film 40 provided on the piezoelectric layer 30 located between the wiring electrodes 33 having different electric potentials and not provided with electrodes at the portion other than the functional electrode portion) concerns an excitation frequency of the bulk wave. On the other hand, the thickness of a portion denoted by reference sign t1 (that is to say, the thickness of the dielectric film 40 provided on the wiring electrodes 33) does not concern the excitation frequency of bulk wave.

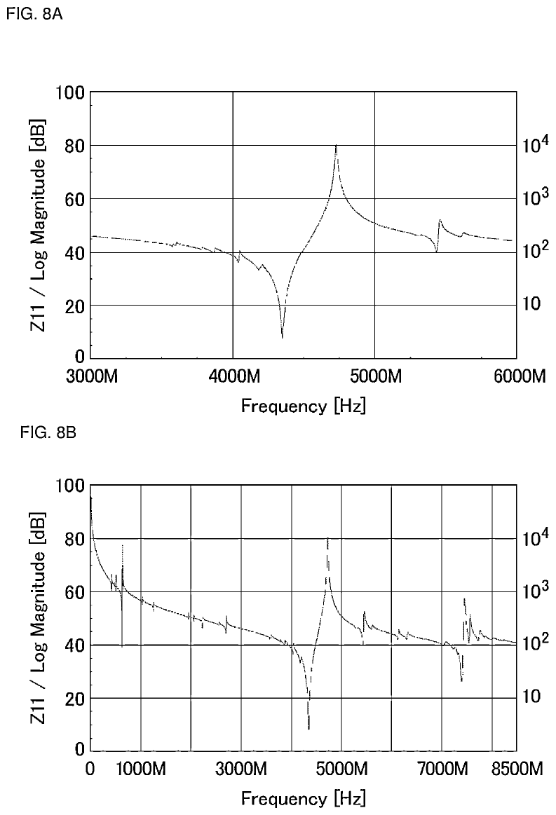

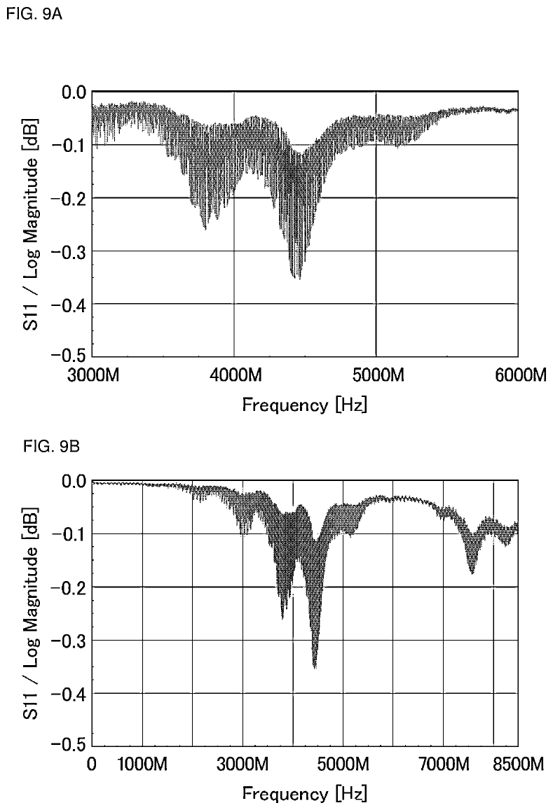

FIG. 8A is a graph depicting an example of resonator characteristics in a narrow band. FIG. 8B is a graph depicting an example of resonator characteristics in a wide band. FIG. 9A is a graph depicting an example of characteristics of the bulk wave in the narrow band. FIG. 9B is a graph depicting an example of characteristics of the bulk wave in the wide band.

As described above, both of the wave used in the device characteristics by the functional electrode portion (the resonator) and the bulk wave excited at the portion other than the functional electrode portion (such as the routed wiring portion) are waves of the same type which are excited in or substantially in the same frequency band. By thinning the dielectric film in the portion other than the functional electrode portion, it is possible to set bulk wave responses plotted in FIGS. 9A and 9B to higher frequencies, thus shifting the frequencies of the resonators from the frequencies of the bulk wave responses.

The following simulation was performed in order to confirm advantageous effects of example embodiments of the present invention.

FIG. 10 is a cross-sectional view schematically illustrating configuration of the portion other than the functional electrode portion used for the simulation.

As illustrated in FIG. 10, the simulation was conducted as follows. Specifically, an electric field was applied to the piezoelectric layer 30 by using an electric signal applied to the wiring electrode 33, such that an acoustic wave was excited and radiated. This was reflected from a bottom surface of the support 20, and was converted into an electric signal again by the piezoelectric layer 30 and the wiring electrodes 33.

The support 20 includes a support substrate 20A and an intermediate layer 20B. Materials and thicknesses of the support substrate 20A, the intermediate layer 20B, the piezoelectric layer 30, and the dielectric film 40 are illustrated in FIG. 10.

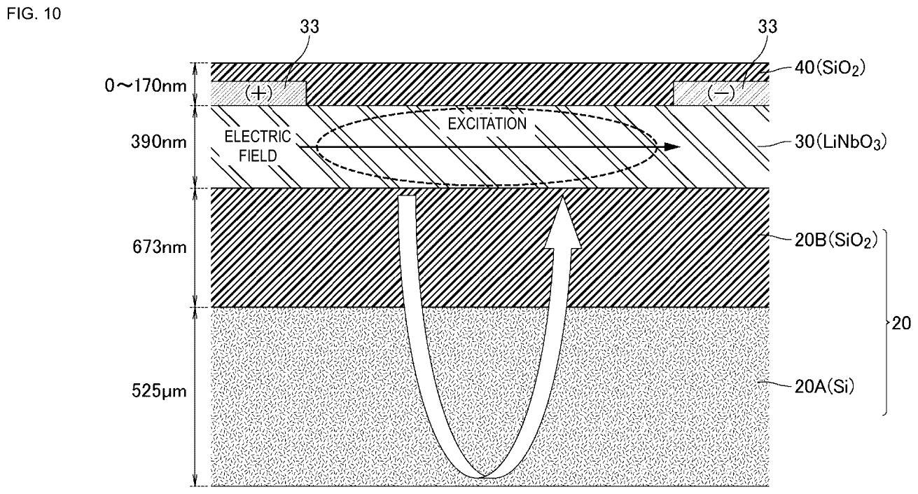

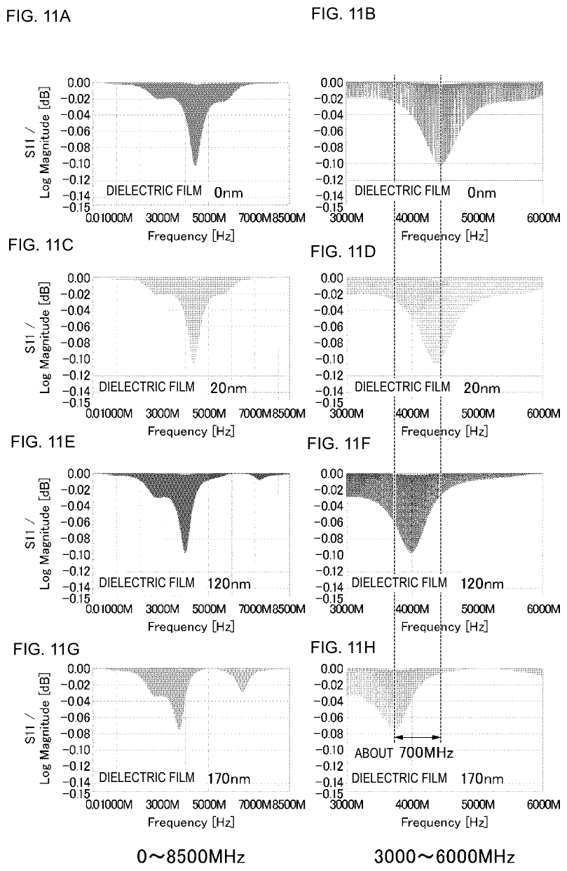

FIGS. 11A to 11H are graphs depicting simulation results.

As plotted in FIGS. 11A to 11H, it is apparent that a peak is shifted to a high-frequency side by thinning the dielectric film. Using this aspect, it is possible to avoid the occurrence of tiny ripples within a filter band.

### Second Example Embodiment

In an acoustic wave device according to a second example embodiment of the present invention, an energy confinement layer is an acoustic reflection layer.

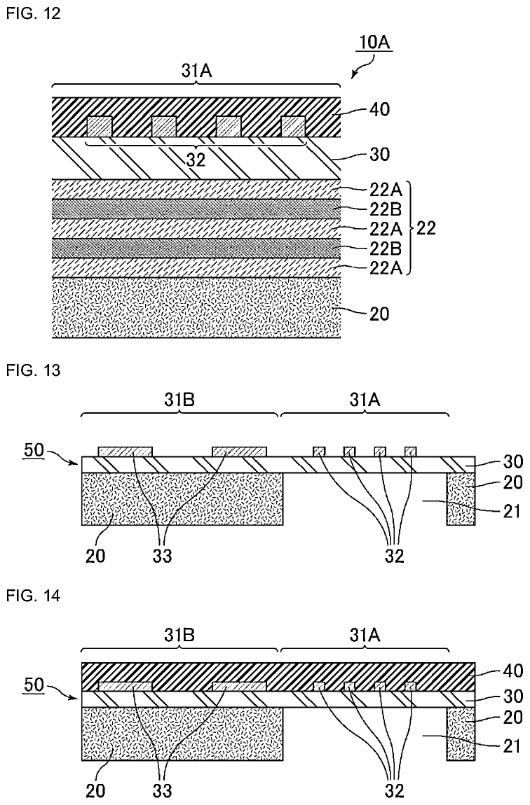

FIG. 12 is a cross-sectional view schematically illustrating an example of a functional electrode portion in the acoustic wave device according to the second example embodiment of the present invention.

An acoustic wave device 10A illustrated in FIG. 12 includes the support 20, the piezoelectric layer 30, the functional electrodes 32, and the dielectric film 40.

The support 20 includes an acoustic reflection layer 22 as another example of the energy confinement layer at one principal surface (an upper principal surface in FIG. 12). The acoustic reflection layer 22 is, for example, an acoustic Bragg reflector.

The acoustic reflection layer 22 includes first layers 22A having first acoustic impedance, and second layers 22B being laminated on the first layers 22A and having second acoustic impedance higher than the first acoustic impedance. As illustrated in FIG. 12, it is preferable to alternately laminate the first layers 22A and the second layers 22B in the acoustic reflection layer 22.

The acoustic impedance of the first layer 22A is lower than the acoustic impedance of the second layer 22B. For example, the first layer 22A is made of silicon oxide (SiOₓ) such as silicon dioxide (SiO₂). The first layer 22A may be made of, for example, an inorganic oxide other than silicon oxide or a metal such as Al and Ti instead.

The acoustic impedance of the second layer 22B is higher than the acoustic impedance of the first layer 22A. For example, the second layer 22B is made of a metal such as Pt, W, Mo, and Ta or a dielectric body such as tungsten oxide, tantalum oxide, hafnium oxide, hafnium nitride, and aluminum nitride.

The support 20 includes a support substrate. The support 20 may include an intermediate layer on one principal surface provided with the piezoelectric layer 30. For example, the support 20 may include the support substrate, and the intermediate layer provided between the support substrate and the piezoelectric layer.

The piezoelectric layer 30 is provided on the one principal surface of the support 20 and covers the acoustic reflection layer 22.

The functional electrodes 32 are provided on at least the one principal surface of the piezoelectric layer 30, and at least a portion of the functional electrodes 32 overlaps the acoustic reflection layer 22 when viewed in the thickness direction (the vertical direction in FIG. 12) of the piezoelectric layer 30. The functional electrodes 32 may be provided to entirely or substantially entirely overlap the acoustic reflection layer 22 or the functional electrodes 32 may be provided to partially overlap the acoustic reflection layer 22 when viewed in the thickness direction of the piezoelectric layer 30.

The piezoelectric layer 30 is includes the functional electrode portion 31A including the functional electrodes 32, and a portion (not illustrated) other than the functional electrode portion. The functional electrode portion 31A corresponds to the resonator.

The dielectric film 40 is provided on the principal surface (the principal surface on the upper side in FIG. 12) of the piezoelectric layer 30 on an opposite side from the acoustic reflection layer 22, and is provided in at least the functional electrode portion 31A. At the principal surface (the principal surface on the upper side in FIG. 12) of the piezoelectric layer 30 on the opposite side from the acoustic reflection layer 22, the dielectric film 40 may be provided in the functional electrode portion 31A and the portion (not illustrated) other than the functional electrode portion, or provided only in the functional electrode portion 31A.

Although not illustrated, as with the first example embodiment, the thickness of at least a portion of the dielectric film 40 provided in the functional electrode portion 31A is larger than the thickness of the dielectric film 40 provided in the portion other than the functional electrode portion. Accordingly, the generation frequency of the bulk wave can be shifted from the frequency band used by the device. Thus, it is possible to reduce an impact of ripples generated by the bulk wave on the device characteristics.

Here, the thickness of the entire or substantially the entire dielectric film 40 provided in the functional electrode portion 31A may be larger than the thickness of the dielectric film 40 provided in the portion other than the functional electrode portion, or the thickness of a portion of the dielectric film 40 provided in the functional electrode portion 31A may be larger than the thickness of the dielectric film 40 provided in the portion other than the functional electrode portion. Alternatively, the thickness of the dielectric film 40 provided in the portion other than the functional electrode portion may be equal to zero. That is to say, the dielectric film 40 need not be provided in the portion other than the functional electrode portion.

Other configurations are shared by the first example embodiment.

An example of a method of manufacturing the acoustic wave device according to an example embodiment of the present invention will be described below.

The example method of manufacturing the acoustic wave device according to an example embodiment of the present invention includes a step of preparing an intermediate structure, a step of forming a dielectric film at the intermediate structure, and a step of adjusting a thickness of the dielectric film formed at the intermediate structure.

FIG. 13 is a cross-sectional view schematically illustrating an example of the step of preparing an intermediate structure.

An intermediate structure 50 including the support 20, the piezoelectric layer 30, and the functional electrodes 32 is prepared as illustrated in FIG. 13.

The support 20 includes the energy confinement layer such as the hollow portion 21 at the one principal surface (the upper principal surface in FIG. 13). The energy confinement layer may instead be the acoustic reflection layer 22 (see FIG. 12), for example.

The piezoelectric layer 30 is provided in the one principal surface of the support 20 and covers the energy confinement layer such as the hollow portion 21.

The functional electrodes 32 are provided on at least the one principal surface of the piezoelectric layer 30, and at least a portion of the functional electrodes 32 overlaps the energy confinement layer such as the hollow portion 21 when viewed in the thickness direction (the vertical direction in FIG. 13) of the piezoelectric layer 30.

The piezoelectric layer 30 is formed from the functional electrode portion 31A including the functional electrodes 32, and the portion 31B other than the functional electrode portion. The functional electrode portion 31A corresponds to the resonator.

The portion 31B other than the functional electrode portion is the routed wiring portion, for example. In this case, the portion 31B other than the functional electrode portion is provided with the wiring electrodes 33 to be connected to the functional electrodes 32.

FIG. 14 is a cross-sectional schematically illustrating an example of the step of forming a dielectric film at the intermediate structure.

As illustrated in FIG. 14, the dielectric film 40 is formed on the intermediate structure 50 and covers at least the functional electrode portion 31A on the principal surface (the principal surface on the upper side in FIG. 14) of the piezoelectric layer 30 on the opposite side from the energy confinement layer such as the hollow portion 21. The dielectric film 40 may be formed on the intermediate structure 50 to cover the functional electrode portion 31A and the portion 31B other than the functional electrode portion on the principal surface (the principal surface on the upper side in FIG. 14) of the piezoelectric layer 30 on the opposite side from the energy confinement layer such as the hollow portion 21, or the dielectric film 40 may be formed on the intermediate structure 50 to cover only the functional electrode portion 31A.

In the example illustrated in FIG. 14, the thick dielectric film 40 is formed on the entire or substantially the entire piezoelectric layer 30 on the support 20.

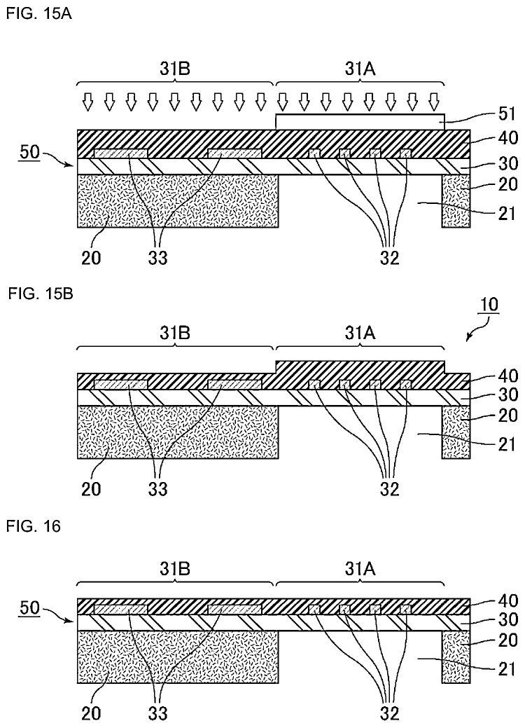

FIGS. 15A and 15B are cross-sectional views schematically illustrating an example of the step of adjusting a thickness of the dielectric film formed on the intermediate structure.

As illustrated in FIGS. 15A and 15B, the thickness of the dielectric film 40 formed on the intermediate structure 50 is adjusted such that the thickness of at least a portion of the dielectric film 40 provided in the functional electrode portion 31A becomes larger than the thickness of the dielectric film 40 provided in the portion 31B other than the functional electrode portion.

Here, the thickness of the entire or substantially the entire dielectric film 40 provided om the functional electrode portion 31A may be larger than the thickness of the dielectric film 40 provided in the portion 31B other than the functional electrode portion, or the thickness of a portion of the dielectric film 40 provided in the functional electrode portion 31A may be larger than the thickness of the dielectric film 40 provided in the portion 31B other than the functional electrode portion. Alternatively, the thickness of the dielectric film 40 provided in the portion 31B other than the functional electrode portion may be equal to zero. That is to say, the dielectric film 40 need not be provided in the portion 31B other than the functional electrode portion.

In the example illustrated in FIGS. 15A and 15B, the dielectric film 40 provided in the portion 31B other than the functional electrode portion is removed. For example, a resist 51 is formed only in the functional electrode portion 31A and the dielectric film 40 provided in the portion 31B other than the functional electrode portion is removed by etching.

FIG. 16 is a cross-sectional view schematically illustrating another example of the step of forming a dielectric film at the intermediate structure.

In the example illustrated in FIG. 16, the thin dielectric film 40 is formed on the entire piezoelectric layer 30 on the support 20.

FIGS. 17A and 17B are cross-sectional views schematically illustrating another example of the step of adjusting a thickness of the dielectric film formed at the intermediate structure.

In the example illustrated in FIGS. 17A and 17B, an additional dielectric film 40 is formed on the dielectric film 40 provided in the functional electrode portion 31A. For instance, the resist 51 is formed in the portion 31B other than the functional electrode portion and the additional dielectric film 40 is formed on the dielectric film 40 provided in the functional electrode portion 31A.

Here, the method illustrated in FIGS. 17A and 17B is also applicable to the frequency adjustment of the functional electrode portion 31A.

After the above-described steps, the acoustic wave device 10 illustrated in FIG. 15B or FIG. 17B is obtained.

### Other Example Embodiments

The acoustic wave device of the present invention is not limited to the above-described example embodiments, and various applications and modifications can be made within the scope of the present invention in light of the configuration of the acoustic wave device, manufacturing conditions thereof, and so forth.

In above-described the example embodiments, the functional electrodes are provided on the opposite side from the support. However, when the energy confinement layer is the hollow portion, the functional electrodes may be provided on the support side.

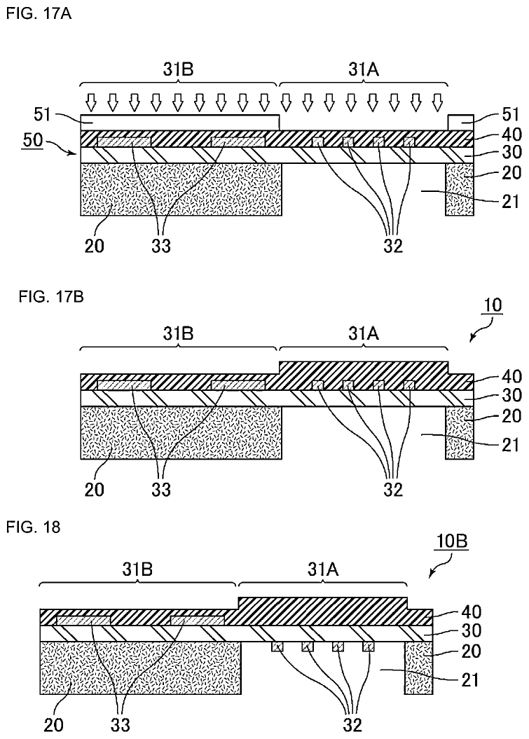

FIG. 18 is a cross-sectional view schematically illustrating another example of the acoustic wave device according to the first example embodiment of the present invention.

In an acoustic wave device 10B illustrated in FIG. 18, the functional electrodes 32 are provided on one principal surface (a principal surface of a lower side in FIG. 18) of the piezoelectric layer 30 located on the support 20 side.

On the other hand, the dielectric film 40 needs to be provided on a principal surface (a principal surface on an upper side in FIG. 18) of the piezoelectric layer 30 on an opposite side from the hollow portion 21 defining and functioning as the energy confinement layer.

Details of an acoustic wave device that uses the thickness-shear mode and a plate wave will be described below by using an acoustic wave device not including a dielectric film as an example. A description will be provided below by using an example in a case where the functional electrodes are the IDT electrodes.

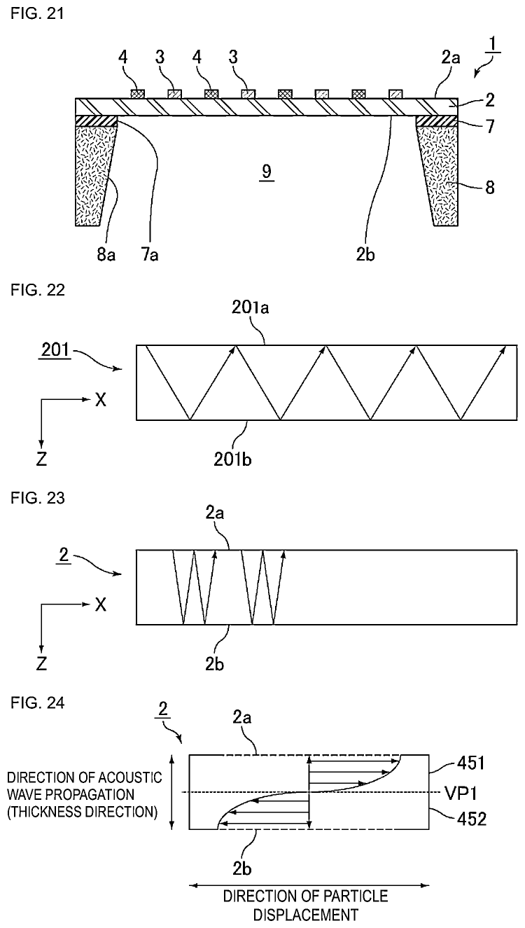

FIG. 19 is a schematic perspective view illustrating external appearance of an example of an acoustic wave device that uses a thickness-shear mode bulk wave. FIG. 20 is a plan view illustrating an electrode structure on a piezoelectric layer of the acoustic wave device depicted in FIG. 19. FIG. 21 is a cross-sectional view of a portion taken along the A-A line in FIG. 19.

An acoustic wave device 1 includes a piezoelectric layer 2 made a LiNbO₃, for example. The piezoelectric layer 2 may be made of, for example, LiTaO₃ instead. Cut-angles of LiNbO₃ or LiTaO₃ are provided by z-cut, for example. However, the cut-angles may be provided by rotary y-cut or x-cut instead. Preferably, for example, a propagation direction of y propagation or x propagation±about 30° is provided. Although a thickness of the piezoelectric layer 2 is not limited to a particular thickness, for example, the thickness is preferably set equal to or greater than about 50 nm and equal to or less than about 1000 nm in order to bring about effective excitation in the thickness-shear mode. The piezoelectric layer 2 includes a first principal surface 2a and a second principal surface 2b that are opposed to each other. An electrode 3 and an electrode 4 are provided on the first principal surface 2a of the piezoelectric layer 2. Here, the electrode 3 is an example of a “first electrode” and the electrode 4 is an example of a “second electrode”. In FIGS. 19 and 20, multiple electrodes 3 include multiple first electrode fingers that are connected to a first busbar electrode 5. Multiple electrodes 4 include multiple second electrode fingers that are connected to a second busbar electrode 6. The multiple electrodes 3 and the multiple electrodes 4 are interdigitated with one another. The electrodes 3 and the electrodes 4 each have a rectangular or substantially rectangular shape and have a length direction. An electrode 3 and an adjacent electrode 4 are opposed to each other in a direction orthogonal or substantially orthogonal to this length direction. These multiple electrodes 3 and 4, the first busbar electrode 5, and the second busbar electrode 6 collectively define the IDT (interdigital transducer) electrodes. Each of the length direction of the electrodes 3 and 4 and the direction orthogonal or substantially orthogonal to the length direction of the electrodes 3 and 4 is a direction intersecting with a thickness direction of the piezoelectric layer 2. In this regard, the electrode 3 and the adjacent electrode 4 can also be considered to be opposed to each other in the direction intersecting with the thickness direction of the piezoelectric layer 2. Further, the length direction of the electrodes 3 and 4 may be interchanged with the direction orthogonal or substantially orthogonal to the length direction of the electrodes 3 and 4 illustrated in FIGS. 19 and 20. Specifically, the electrodes 3 and 4 may extend in a direction of extension of the first busbar electrode 5 and second busbar electrode 6 in FIGS. 19 and 20. In this case, the first busbar electrode 5 and the second busbar electrode 6 extend in a direction of extension of the electrodes 3 and 4 in FIGS. 19 and 20. Moreover, pairs of structures each including the electrode 3 connected to one potential and the electrode 4 connected to another potential being located adjacent to each other are provided in the direction orthogonal or substantially orthogonal to the length direction of the electrodes 3 and 4 described above. Here, the state of the electrode 3 and the electrode 4 being located adjacent to each other does not represent a case where the electrode 3 and the electrode 4 are disposed in such a way as to be in direct contact, but represents a case where the electrode 3 and the electrode 4 are disposed with a clearance therebetween. Meanwhile, when the electrode 3 and the electrode 4 are located adjacent to each other, electrodes inclusive of other electrodes 3 and 4 to be connected to hot electrodes or a ground electrode are not disposed between the relevant electrode 3 and the electrode 4. The number of pairs does not always have to be an integer pair but may also be any of 1.5 pairs, 2.5 pairs, and so forth. A center-to-center distance, that is to say, a pitch between the electrodes 3 and 4 is, for example, preferably in a range from equal to or greater than about 1 μm and equal to or less than about 10 μm. In the meantime, the center-to-center distance between the electrodes 3 and 4 is a distance of connection between the center in a width dimension of the electrode 3 in the direction orthogonal or substantially orthogonal to the length direction of the electrode 3 and the center in a width dimension of the electrode 4 in the direction orthogonal or substantially orthogonal to the length direction of the electrode 4. Moreover, when at least two or more the electrodes 3 or two or more electrodes 4 are present (when there are 1.5 pairs or more of electrode sets assuming that each electrode set includes a pair of the electrodes 3 and 4), the center-to-center distance between the electrodes 3 and 4 represents an average value of the respective center-to-center distances of the adjacent electrodes 3 and 4 among the electrodes 3 and 4 in the 1.5 pairs or more. In the meantime, the widths of the electrodes 3 and 4, that is to say, dimensions in a direction of opposition of the electrodes 3 and 4 are, for example, preferably in a range from equal to or greater than about 150 nm and equal to or less than about 1000 nm.

When the z-cut piezoelectric layer is used in the present example embodiment, the direction orthogonal or substantially orthogonal to the length direction of the electrodes 3 and 4 is equivalent to a direction orthogonal or substantially orthogonal to a direction of polarization of the piezoelectric layer 2. This is not applicable when a piezoelectric body having a different cut-angle is used as the piezoelectric layer 2. Here, the term “orthogonal” is not limited only to a case of being strictly orthogonal but may also include a case of being substantially orthogonal (where an angle formed between the direction orthogonal to the length direction of the electrodes 3 and 4 and the direction of polarization may be equivalent to about 90°+10°, for example).

A support substrate 8 is laminated on the second principal surface 2b side of the piezoelectric layer 2 while interposing an intermediate layer (also referred to as a joining layer) 7 therebetween. The intermediate layer 7 and the support substrate 8 each have a frame shape and include cavities 7a and 8a as illustrated in FIG. 21, and a hollow portion 9 is provided accordingly. The hollow portion 9 is provided in order not to block vibration in an excitation region C (see FIG. 20) of the piezoelectric layer 2. Accordingly, the support substrate 8 is laminated on the second principal surface 2b while interposing the intermediate layer 7 therebetween at a position not overlapping a portion where at least a pair of electrodes 3 and 4 are provided. Here, the intermediate layer 7 does not always have to be provided. Accordingly, the support substrate 8 may be laminated either directly or indirectly on the second principal surface 2b of the piezoelectric layer 2.

The intermediate layer 7 is made of silicon oxide, for example. Nonetheless, an appropriate insulating material such as, for example, silicon oxynitride and alumina can be used in addition to silicon oxide. The support substrate 8 is made of Si, for example. A plane orientation on a surface on the piezoelectric layer 2 side of Si may be (100), (110), or (111). Preferably, for example, high-resistance Si having a resistivity equal to or greater than about 4 kΩ is used. Nevertheless, for example, the support substrate 8 can also be made my using an insulating material or a semiconductor material as appropriate. For example, as the material of the support substrate 8, it is possible to use piezoelectric bodies such as aluminum oxide, lithium tantalate, lithium niobate, and quartz, various ceramics such as alumina, magnesia, sapphire, silicon nitride, aluminum nitride, silicon carbide, zirconia, cordierite, mullite, steatite, and forsterite, dielectric bodies such as diamond and glass, semiconductors such as gallium nitride, and so forth.

The multiple electrodes 3 and 4 as well as the first busbar electrode 5 and the second busbar electrode 6 are made of a metal or an alloy such as, for example, Al and AlCu alloy as appropriate. In the present example embodiment, the electrodes 3 and 4 as well as the first busbar electrode 5 and the second busbar electrode 6 have, for example, a structure including an Al film laminated on a Ti film. Here, a close contact layer other than the Ti film may be used instead.

In driving, an alternating-current voltage is applied between the multiple electrodes 3 and the multiple electrodes 4. To be more precise, the alternating-current voltage is applied between the first busbar electrode 5 and the second busbar electrode 6. Accordingly, it is possible to obtain resonance characteristics by using the thickness-shear mode bulk wave excited by the piezoelectric layer 2. Meanwhile, when the thickness of the piezoelectric layer 2 is defined as the value d and the center-to-center distance between the electrodes 3 and 4 located adjacent to each other among the multiple pairs of the electrodes 3 and 4 is defined as the value p in the acoustic wave device 1, the value d/p is set equal to or less than about 0.5, for example. For this reason, the thickness-shear mode bulk wave can be effectively excited so that favorable resonance characteristics can be obtained. More preferably, for example, the value d/p is set equal to or less than about 0.24. In this case, it is possible to obtain even more favorable resonance characteristics. Here, when at least any of the electrodes 3 and 4 include more than one as in the present example embodiment, or in other words, in the case where the pair of the electrodes 3 and 4 and one of the electrodes 3 and 4 collectively form 1.5 pairs or more, the center-to-center distance p of the electrodes 3 and 4 located adjacent to one another is an average distance of the center-to-center distances of the respective sets of the electrodes 3 and 4 located adjacent to each other.

Since the acoustic wave device 1 of the present example embodiment has the above-described configuration, a drop in Q-factor is less likely to occur even when the number of pairs of the electrodes 3 and 4 is decreased in an attempt to downsize. This is due to the reason that the acoustic wave device 1 is a resonator which does not require reflectors on both sides, and causes less propagation losses. Meanwhile, the acoustic wave device 1 does not require the reflectors because the acoustic wave device 1 uses the thickness-shear mode bulk wave. A difference between the Lamb wave used in the acoustic wave device of the related art and the above-described thickness-shear mode bulk wave will be described with reference to FIGS. 22 and 23.

FIG. 22 is a schematic elevational cross-sectional view for explaining a Lamb wave that propagates on a piezoelectric film of an acoustic wave device. As illustrated in FIG. 22, in the acoustic wave device as described in Japanese Unexamined Patent Application Publication No. 2012-257019, the wave propagates in a piezoelectric film 201 as indicated with arrows. Here, in the piezoelectric film 201, a first principal surface 201a is opposed to a second principal surface 201b, and a thickness direction connecting the first principal surface 201a to the second principal surface 201b is z direction. A direction of arrangement of electrode fingers of an IDT electrode is x direction. As illustrated in FIG. 22, regarding the Lamb wave, the wave propagates in the x direction as illustrated therein. Because of being the plate wave, the piezoelectric film 201 vibrates as a whole. However, since the wave propagates in the x direction, resonance characteristics are obtained by disposing reflectors on both sides. As a consequence, propagation losses of the wave are caused and the Q-factor drops in an attempt to downsize, that is to say, when the number of pairs of the electrode fingers is reduced.

On the other hand, FIG. 23 is a schematic elevational cross-sectional view for explaining the thickness-shear mode bulk wave that propagates on a piezoelectric layer of the acoustic wave device. As illustrated in FIG. 23, vibration displacement occurs in a thickness-shear direction in the acoustic wave device 1 of the present example embodiment. Accordingly, the wave propagates and resonates substantially in the direction to connect between the first principal surface 2a and the second principal surface 2b of the piezoelectric layer 2, that is to say, in the z direction. In other words, an x-direction component of the wave is significantly smaller than a z-direction component thereof. Moreover, no reflectors are required because the resonance characteristics are obtained by this propagation of the wave in the z direction. As a consequence, no propagation losses associated with propagation to the reflectors occur. Accordingly, a decrease in Q-factor is less likely to occur even when the number of pairs of electrode pairs including the electrodes 3 and 4 is reduced in an attempt to promote downsizing.

FIG. 24 is a diagram illustrating a direction of amplitude of the thickness-shear mode bulk wave. As illustrated in FIG. 24, a direction of amplitude of the thickness-shear mode bulk wave in a first region 451 included in the excitation region C of the piezoelectric layer 2 is reverse to that in a second region 452 included in the excitation region C. FIG. 24 schematically illustrates the bulk wave in a case of applying a voltage between the electrode 3 and the electrode 4, which brings about a higher potential at the electrode 4 than that at the electrode 3. The first region 451 is a region in the excitation region C, which is located between the first principal surface 2a and a virtual plane VP1 that is orthogonal or substantially orthogonal to the thickness direction of the piezoelectric layer 2 and bisects the piezoelectric layer 2. The second region 452 is a region in the excitation region C, which is located between the virtual plane VP1 and the second principal surface 2b.

As described above, at least one pair of electrodes including the electrode 3 and the electrode 4 are disposed in the acoustic wave device 1. However, since the acoustic wave device 1 is not configured to propagate the wave in the x direction, the number of pairs of these electrodes 3 and 4 does not always have to be multiple pairs. That is to say, at least one pair of electrodes needs to be provided therein.

For example, the electrode 3 is an electrode to be connected to a hot potential and the electrode 4 is an electrode to be connected to a ground potential. Nevertheless, the electrode 3 may be connected the ground potential and the electrode 4 may be connected to the hot ground potential instead. In the present example embodiment, at least the one pair of electrodes include either the electrode to be connected to the hot potential or the electrode to be connected to the ground potential as described above, and no floating electrodes are provided therein.

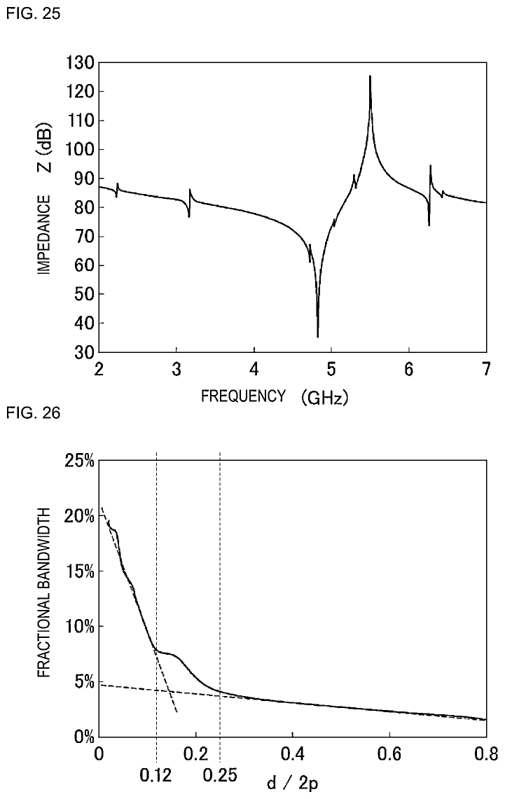

FIG. 25 is a diagram illustrating an example of resonance characteristics of the acoustic wave device illustrated in FIG. 19. Example design parameters of the acoustic wave device 1 that obtains these resonance characteristics are as follows:
piezoelectric layer 2: LiNbO₃ having Euler angles (0°, 0°, 90°), thickness=about 400 nm, a length of a region where the electrode 3 overlaps the electrode 4 when viewed in the direction orthogonal or substantially orthogonal to the length direction of the electrodes 3 and 4, namely, the excitation region C=about 40 μm, the number of pairs of electrodes formed from the electrodes 3 and 4=21 pairs, a center distance between the electrodes=about 3 μm, a width of the electrodes 3 and 4=about 500 nm, and the value d/p=about 0.133;
intermediate layer 7: a silicon oxide film having a thickness of about 1 μm; and
support substrate 8: Si.

Here, the length of the excitation region C is a dimension of the excitation region C along the length direction of the electrodes 3 and 4.

In the acoustic wave device 1, the distances between the electrodes of the electrode pairs including the electrodes 3 and 4 are set equal or substantially equal among all the multiple pairs. In other words, the electrodes 3 and the electrodes 4 are disposed at regular pitches.

As apparent from FIG. 25, favorable resonance characteristics with a fractional bandwidth of, for example, about 12.5% are obtained in spite of not being provided with reflectors.

In the meantime, when the thickness of the above-mentioned piezoelectric layer 2 is defined as the value d and the center-to-center distance of the electrodes between the electrode 3 and the electrode 4 is defined as the value p, the value d/p is, for example, preferably equal to or less than about 0.5 or more preferably equal to or less than about 0.24 in the present example embodiment as described above. This will be described with reference to FIG. 26.

As with the acoustic wave device that obtained the resonance characteristics depicted in FIG. 25, multiple acoustic wave devices were obtained while changing values d/2p thereof. FIG. 26 is a diagram illustrating a relationship between the value d/2p when defining the center-to-center distance between the electrodes located adjacent to each other as the value p while defining the thickness of the piezoelectric layer as the value d and fractional bandwidths as resonators of the acoustic wave devices.

As apparent from FIG. 26, when the value d/2p exceeds about 0.25, that is to say, when the value d/p>about 0.5, the fractional bandwidth falls below about 5% even when the value d/p is adjusted. On the other hand, when the value d/2p≤about 0.25, that is to say, when the value d/p≥about 0.5, the fractional bandwidth can be set equal to or greater than about 5% by changing the value d/p within that range. In other words, it is possible to construct a resonator having a high coupling coefficient. Meanwhile, when the value d/2p is equal to or less than about 0.12, that is to say, when the value d/p is equal to or less than about 0.24, the fractional bandwidth can be increased to about 7% or above. In addition, when the value d/p is adjusted within this range, it is possible to obtain the resonator having an even wider fractional bandwidth and to achieve a resonator having an even higher coupling coefficient. Accordingly, it is understood that the resonator having the high coupling coefficient by using the above-described thickness-shear mode bulk wave can be constructed by setting the value d/p equal to or less than about 0.5, for example.

Here, as described above, at least one pair of electrodes may include one pair and the value p is defined as the center-to-center distance between the electrodes 3 and 4 that are located adjacent to each other in the case of one pair of electrodes. Meanwhile, in the case of the electrodes of 1.5 pairs or more, an average distance of the center-to-center distances of the electrodes 3 and 4 that are located adjacent to one another may be defined as the value p.

Meanwhile, regarding the thickness d of the piezoelectric layer, a value obtained by averaging thicknesses may be used in a case where the piezoelectric layer 2 has a variation in thickness.

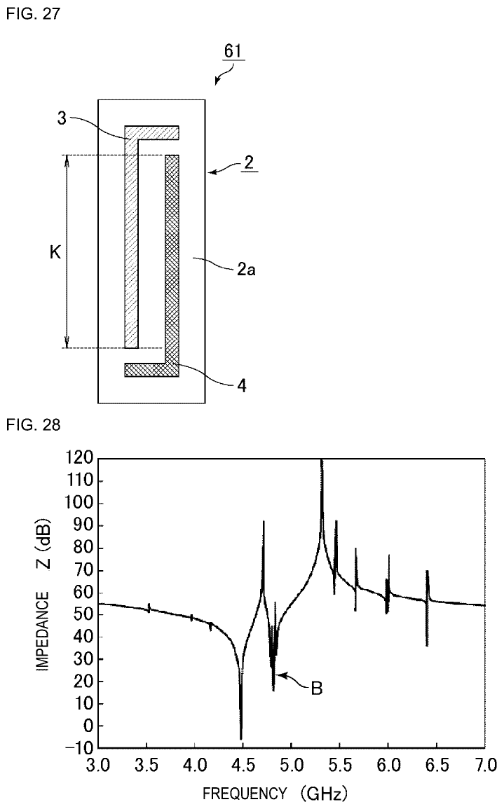

FIG. 27 is a plan view of another example of an acoustic wave device that uses the thickness-shear mode bulk wave.

In an acoustic wave device 61, a pair of electrodes including the electrode 3 and the electrode 4 are provided on the first principal surface 2a of the piezoelectric layer 2. Here, reference sign K in FIG. 27 represents an intersecting width. As described above, in the acoustic wave device of the present example embodiment, the number of pairs of electrodes may be one pair. In this case as well, the thickness-shear mode bulk wave can be effectively excited as long as the value d/p is, for example, equal to or less than about 0.5.

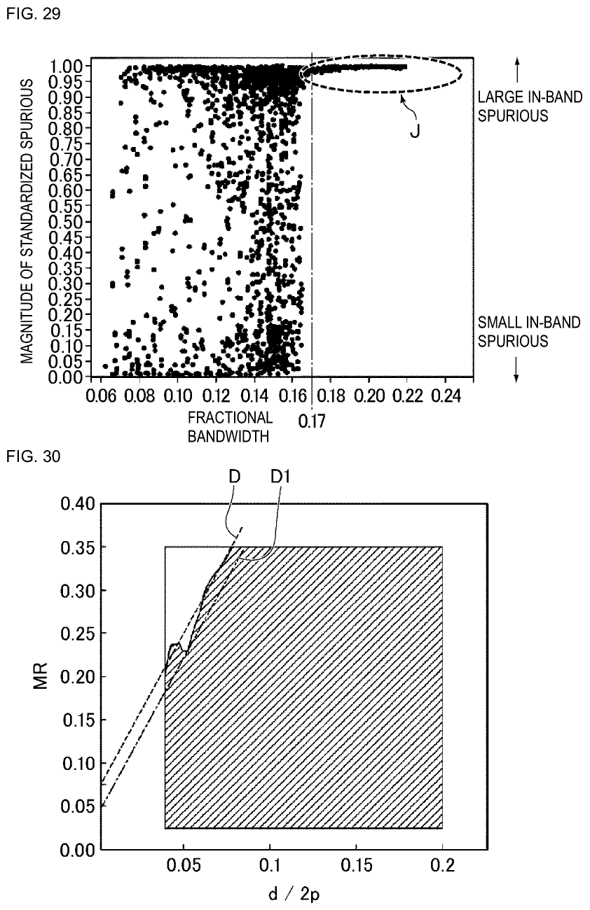

Preferably, in the acoustic wave device of the present example embodiment, a metallization ratio MR of certain electrodes 3 and 4 that are located adjacent to each other among the multiple electrodes 3 and 4 relative to the excitation region, which is the region where the electrodes 3 and 4 being located adjacent to each other overlap when viewed in a direction of opposition thereof, satisfies MR≤about 1.75 (d/p)+0.075, for example. In this case, it is possible to reduce the spurious response effectively. This will be described with reference to FIGS. 28 and 29.

FIG. 28 is a reference diagram illustrating an example of the resonance characteristics of the acoustic wave device depicted in FIG. 19. A spurious response indicated by an arrow B emerges between a resonant frequency and an anti-resonant frequency. Here, the value d/p was set equal to about 0.08 and the Euler angles of LiNbO₃ were set to (0°, 0°, 90°). Meanwhile, the metallization ratio was set to MR=about 0.35.

The metallization ratio MR will be described with reference to FIG. 20. When focusing on a pair of the electrodes 3 and 4 in the electrode structure of FIG. 20, it is assumed that only this pair of electrodes 3 and 4 is provided therein. In this case, a portion surrounded by a dash-dotted line C will be the excitation region. This excitation region is a region of the electrode 3 overlapping the electrode 4, a region of the electrode 4 overlapping the electrode 3, and a region between the electrode 3 and the electrode 4 where the electrode 3 and the electrode 4 overlap when the electrode 3 and the electrode 4 are viewed in the direction orthogonal to the length direction of the electrodes 3 and 4, that is to say, in the direction of opposition. Moreover, the area of the electrodes 3 and 4 in the excitation region C relative to the area of this excitation region is the metallization ratio MR. In other words, the metallization ratio MR is a ratio of the area of the portion of metallization relative to the area of the excitation region.

Here, when multiple pairs of the electrodes are provided, the ratio of the metallization portions included in all of the excitation regions relative to a sum of the areas of the excitation regions may be defined as the value MR.

FIG. 29 is a diagram illustrating a relationship between a fractional bandwidth when constructing numerous acoustic wave resonators in accordance with the present example embodiment and a phase rotation amount of impedance of a spurious response standardized at about 180 degrees as a magnitude of the spurious response. Here, the fractional bandwidth was adjusted by variously changing a film thickness of the piezoelectric layer and dimensions of the electrodes. In the meantime, although FIG. 29 represents a result in a case of using the piezoelectric layer made of, for example, z-cut LiNbO₃, a case of using the piezoelectric layer of a different cut-angle also shows a similar tendency.

The spurious response grows as large as about 1.0 in a region surrounded by an ellipse J in FIG. 29. As apparent from FIG. 29, when the fractional bandwidth exceeds about 0.17, or in other words, when the fractional bandwidth exceeds about 17%, the large spurious response at a spurious level equal to or greater than about 1 emerges in a pass band even when parameters constituting the fractional bandwidth are changed. Specifically, as in the resonance characteristics depicted in FIG. 28, the large spurious response indicated by the arrow B is generated in the band. Therefore, the fractional bandwidth is, for example, preferably equal to or less than about 17%. In this case, the spurious response can be reduced by adjusting the film thickness of the piezoelectric layer 2, the dimensions of the electrodes 3 and 4, and the like.

FIG. 30 is a diagram illustrating a relationship among the value d/2p, the metallization ratio MR, and the fractional bandwidth. Regarding the above-described acoustic wave device, various acoustic wave devices having different values d/2p and MR were constructed and fractional bandwidths thereof were measured.

A portion on a right side of a dashed line D in FIG. 30 illustrated with hatching is a region where the fractional bandwidth is equal to or less than about 17%. A boundary between this region with the hatching and a region without hatching is expressed by MR=about 3.5 (d/2p)+0.075. In other words, MR=about 1.75 (d/p)+0.075 holds true. Accordingly, for example, MR≤about 1.75 (d/p)+0.075 is preferable. In this case, it is easier to set the fractional bandwidth equal to or less than about 17%. For example, a region on a right side of MR=about 3.5 (d/2p)+0.05 indicated with a dash-dotted line D1 in FIG. 30 is more preferable. In other words, the fractional bandwidth can surely be set equal to or less than about 17% when MR≤about 1.75 (d/p)+0.05 holds true.

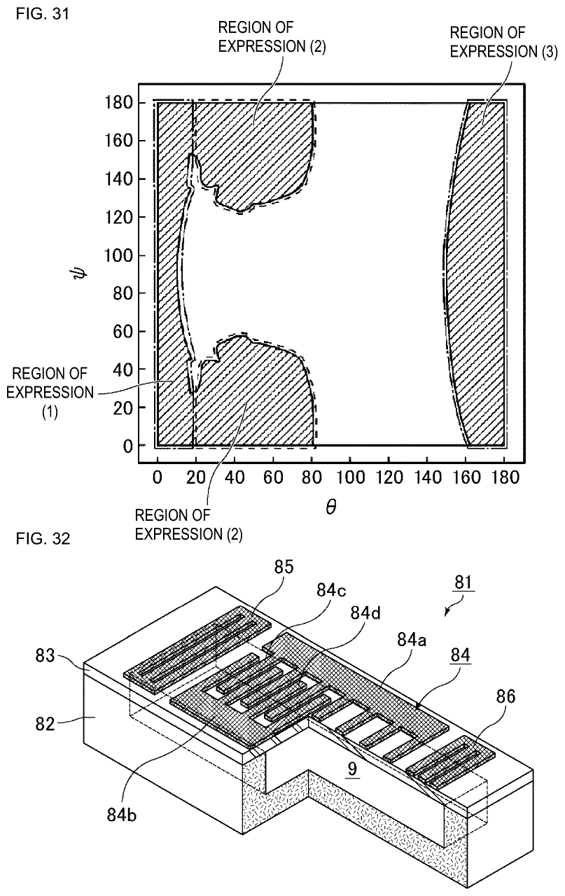

FIG. 31 is a diagram illustrating a map of the fractional bandwidth relative to Euler angles (0°, e, v) of LiNbO₃ in a case of bringing the value d/p infinitesimally close to 0.

Portions in FIG. 31 illustrated with hatching are regions where the fractional bandwidth at least equal to or greater than 5% is available. When ranges of the regions are approximated, the ranges are expressed by the following Expression (1), Expression (2), and Expression (3):

(0°+10°,0° to 20°,arbitrary ψ) Expression (1);

(0°+10°,20° to 80°,0° to 60°(1−(θ−50)²/900)^{1/2}) or

(0°+10°,20° to 80°,[180°-60°(1−(θ−50)²/900)^{1/2}] to 180°) Expression (2); and

(0°+10°,[180°-30° (1−(ψ−90)²/8100)^{1/2}] to 180°,arbitrary ψ) Expression (3).

Accordingly, it is preferable to provide the case of the range of Euler angles of any of the above-mentioned Expression (1), Expression (2), and Expression (3) because the fractional bandwidth can be sufficiently widened.

FIG. 32 is a partially cutaway perspective view for explaining an example of an acoustic wave device that uses a Lamb wave.

An acoustic wave device 81 includes a support substrate 82. A recess that is open upward is provided to the support substrate 82. A piezoelectric layer 83 is laminated on the support substrate 82, thus the hollow portion 9 is provided. An IDT electrode 84 is provided above this hollow portion 9 and on the piezoelectric layer 83. Reflectors 85 and 86 are provided on both sides in a direction of acoustic wave propagation of the IDT electrode 84. An outer peripheral edge of the hollow portion 9 is indicated with a dashed line in FIG. 32. Here, the IDT electrode 84 includes a first busbar electrode 84a and a second busbar electrode 84b, as well as electrodes 84c as multiple first electrode fingers and electrodes 84d as multiple second electrode fingers. The multiple electrodes 84c are connected to the first busbar electrode 84a. The multiple electrodes 84d are connected to the second busbar electrode 84b. The multiple electrodes 84c and the multiple electrodes 84d are interdigitated with one another.

In the acoustic wave device 81, the Lamb wave as the plate wave is excited by applying an alternating-current electric field to the IDT electrode 84 on the hollow portion 9. Then, since the reflectors 85 and 86 are provided on both sides, it is possible to obtain the resonance characteristics attributed to the above-mentioned Lamb wave.

As described above, an acoustic wave device according to an example embodiment of the present invention may be configured to use the plate wave, such as the Lamb wave.

Alternatively, an acoustic wave device according to an example embodiment of the present invention may be configured to use a bulk wave. Specifically, an acoustic wave device according to an example embodiment of the present invention is also applicable to a bulk acoustic wave (BAW) element. In this case, the upper electrode and the lower electrode define and function as the functional electrodes.

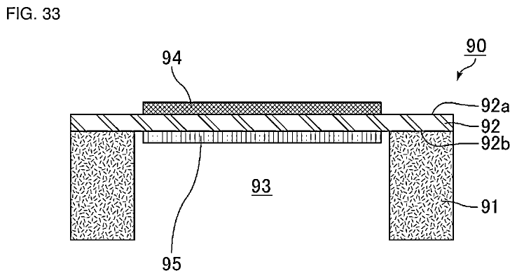

FIG. 33 is a cross-sectional view schematically illustrating an example of an acoustic wave device that uses the bulk wave.

An acoustic wave device 90 includes a support substrate 91. A hollow portion 93 penetrates the support substrate 91. A piezoelectric layer 92 is laminated on the support substrate 91. An upper electrode 94 is provided on a first principal surface 92a of the piezoelectric layer 92 and a lower electrode 95 is provided on a second principal surface 92b of the piezoelectric layer 92. Although not illustrated, an intermediate layer may be provided between the support substrate 91 and the piezoelectric layer 92.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including an energy confinement layer on one principal surface;
a piezoelectric layer on the one principal surface of the support and covering the energy confinement layer;
a functional electrode on at least one principal surface of the piezoelectric layer, and at least partially overlapping the energy confinement layer when viewed in a thickness direction of the piezoelectric layer; and
a dielectric film on a principal surface of the piezoelectric layer on an opposite side from the energy confinement layer; wherein
the piezoelectric layer includes a functional electrode portion including the functional electrode, and a portion other than the functional electrode portion;
the dielectric film is provided in at least the functional electrode portion; and
a thickness of at least a portion of the dielectric film provided in the functional electrode portion is larger than a thickness of the dielectric film provided in the portion other than the functional electrode portion.

2. The acoustic wave device according to claim 1, wherein the energy confinement layer includes a hollow portion.

3. The acoustic wave device according to claim 1, wherein
the energy confinement layer includes an acoustic reflection layer; and
the acoustic reflection layer includes:
a first layer having a first acoustic impedance; and
a second layer being laminated on the first layer and having a second acoustic impedance higher than the first acoustic impedance.

4. The acoustic wave device according to claim 1, wherein the support includes:
a support substrate; and
an intermediate layer on the support substrate.

5. The acoustic wave device according to claim 1, wherein the functional electrode includes:
one or more first electrodes;
a first busbar electrode to which the one or more first electrodes are connected;
one or more second electrodes; and
a second busbar electrode to which the one or more second electrodes are connected.

6. The acoustic wave device according to claim 5, wherein a thickness of the piezoelectric layer is equal to or less than a value of about 2p when a center-to-center distance between a first electrode and a second electrode located adjacent to each other among the one or more first electrodes and the one or more second electrodes is defined as a value p.

7. The acoustic wave device according to claim 1, wherein the piezoelectric layer includes lithium niobate or lithium tantalate.

8. The acoustic wave device according to claim 5, wherein d/p≤about 0.5 is satisfied where a thickness of the piezoelectric layer is defined as a value d and a center-to-center distance between a first electrode and a second electrode located adjacent to each other among the one or more first electrodes and the one or more second electrodes is defined as a value p.

9. The acoustic wave device according to claim 8, wherein d/p≤about 0.24 is satisfied.

10. The acoustic wave device according to claim 5, wherein, MR≤about 1.75 (d/p)+0.075 is satisfied where a metallization ratio being a ratio of an area of the first electrode and the second electrode located adjacent to each other among the one or more first electrodes and the one or more second electrodes relative to an area of an excitation region where the first electrode and the second electrode located adjacent to each other overlap when viewed in a direction of opposition of the first electrode and the second electrode located adjacent to each other is defined as a value MR, a thickness of the piezoelectric layer is defined as a value d, and a center-to-center distance between the first electrode and the second electrode located adjacent to each other is defined as a value p.

11. The acoustic wave device according to claim 10, wherein MR≤about 1.75 (d/p)+0.05.

12. The acoustic wave device according to claim 7, wherein Euler angles (ϕ, θ, ψ) of any of the lithium niobate and the lithium tantalate fall within any of ranges defined by an expression (1), an expression (2), or an expression (3):
(0°±10°,0° to 20°,arbitrary ψ) expression (1);
(0°±10°,20° to 80°,0° to 60° (1−(θ−50)²/900)^{1/2}) or (0°+10°,20° to 80°,[180°-60° (1−(θ−50)²/900)^{1/2}] to 180°) expression (2);
and
(0°+10°,[180°-30° (1−(ψ−90)²/8100)^{1/2}] to 180°,arbitrary ψ) expression (3).

13. The acoustic wave device according to claim 5, wherein the acoustic wave device is configured to generate a thickness-shear mode bulk wave.

14. The acoustic wave device according to claim 1, wherein
the piezoelectric layer includes another principal surface opposed to the one principal surface;
the functional electrode includes an upper electrode on the one principal surface of the piezoelectric layer and a lower electrode on the another principal surface of the piezoelectric layer; and
the upper electrode and the lower electrode are opposed to each other.

15. The acoustic wave device according to claim 14, wherein the piezoelectric layer includes lithium niobate single crystal or lithium tantalate single crystal.

16. A method of manufacturing an acoustic wave device, the method comprising:
preparing an intermediate structure including:
a support including an energy confinement layer on one principal surface;
a piezoelectric layer on the one principal surface of the support and covering the energy confinement layer; and
a functional electrode on at least one principal surface of the piezoelectric layer, and at least partially overlapping the energy confinement layer when viewed in a thickness direction of the piezoelectric layer; wherein
the piezoelectric layer includes a functional electrode portion including the functional electrode, and a portion other than the functional electrode portion;
forming a dielectric film on the intermediate structure to cover at least the functional electrode portion on a principal surface of the piezoelectric layer on an opposite side from the energy confinement layer; and
adjusting a thickness of the dielectric film on the intermediate structure such that a thickness of at least a portion of the dielectric film in the functional electrode portion is larger than a thickness of the dielectric film in the portion other than the functional electrode portion.

17. The method of manufacturing an acoustic wave device according to claim 16, wherein an additional dielectric film is formed on the dielectric film in the functional electrode portion in the step of adjusting the thickness of the dielectric film.

18. The method of manufacturing an acoustic wave device according to claim 16, wherein the dielectric film in the portion other than the functional electrode portion is removed in the step of adjusting the thickness of the dielectric film.
